(19) United States
(12) Patent Application Publication
(10) Pub. No.: US 2008/0026494 A1
(43) Pub. Date: Jan. 31, 2008

(54) Method of fabricating a terbium-doped electroluminescence device via metal organic deposition processes

(75) Inventors: Wei-Wei Zhuang, Vancouver, WA (US); Yoshi Ono, Camas, WA (US); Wei Gao, Vancouver, WA (US); Tingkai Li, Vancouver, WA (US)

Correspondence Address: David C. Ripma;Sharp Laboratories of America, Inc., 5750 NW Pacific Rim Boulevard, Camas, WA, 97202, US

(73) Assignee: Sharp Laboratories of America, Inc.

(21) Appl. No.: 11/494,181

(22) Filed: Jul. 26, 2006

(51) Int. Cl. H01L 21/00

(52) U.S. Cl. 438/21

(57) ABSTRACT

A method of fabricating an electroluminescent device includes preparing a wafer and a doped-silicon oxide precursor solution. The doped-silicon oxide precursor solution is spin coated onto the wafer to form a doped-silicon oxide thin film on the wafer, which is baked at progressively increasing temperatures. The wafer is then rapidly thermally annealed, further annealed in a wet oxygen ambient atmosphere. A transparent top electrode is deposited on the doped-silicon oxide thin film, which is patterned, etched, and annealed. The doped-silicon oxide thin film and the wafer undergo a final annealing step to enhance electroluminescent properties.

### FIELD OF THE INVENTION

This invention relates to electroluminescent devices, and specifically to a technique for fabricating such a device using a terbium doped semiconductor.

### BACKGROUND OF THE INVENTION

Visible light may be generated and emitted form silicon-based devices, however, such emission has been quite inefficient. Broad visible luminescence from silicon devices was reported early on in semiconductor research, however, the emitted light was not bright and the devices required large amounts of hot carriers to generate the light. Newer materials, particularly those in periodic table groups III-V, are known to be efficient generators of light, however, incorporating such materials into silicon-based devices is difficult, if not impossible. Group Ill-V materials must be crystalline, however, the crystalline structure and the lattice mismatch with silicon pose serious barriers to fabricating light emitting devices.

More recently, it has been shown that either nanocrystal silicon and/or rare earth implanted silicon dioxide materials may be made to emit light. The quantum confinement properties in nanocrystal silicon permits excited states to make an optical transition to a lower energy state. Also, the outer electron orbital shell of rare earth elements can make discrete optical transitions. The commercialization of these technologies has not been made because of low efficiencies, high cost of fabrication, and/or poor reliability of the resultant devices.

It is highly desirable to combine silicon-based electronic circuitry with optoelectronic components through the use of silicon-based light emitters. Because of an indirect band gap, silicon is a very poor material as a light emitting medium. Thus, strategies for fabricating silicon-based optoelectronic devices have concentrated on several SiO₂ related materials, such as rare-earth doped SiO₂, silicon rich silicon oxide, or nanocrystal silicon in silicon dioxide thin films.

Recent published research reported promising results with the Er-doped silicon-rich SiO₂ sensitized with silicon nanocrystals, which are claimed to exhibit comparable electroluminescence efficiency as Ill-V optoelectronic devices, Coffa, Light from Silicon, IEEE Spectrum, pp. 46-49, October 2005 To develop visible Si-based light emitters, terbium doped SiO₂ materials have been studied, Sun et al, Bright green electroluminescence from Tb³⁺ in silicon metal-oxide-semiconductor devices, Journal of Applied Physics 97, 123513 (2005). There are many published papers related to the photoluminescence properties of Tb-doped SiO₂ thin films, however, successful observation of electroluminescence is limited to one report, Sun et al, supra. In this reported technique, a high energy implant of the rare earth species was performed, followed by high temperature anneal and top electrode formation. Some of these steps may not be easily integrated with MOS device process flows. A chemical spin coat technique would be more amenable to process integration and allows greater flexibility in how the material is incorporated. The method of the invention generates a terbium (Tb) doped silicon oxide layer which may be used efficiently to generate light using a highly cost effective method, e.g., spin coating, baking, and annealing, to form an electroluminescent film.

Co-pending U.S. patent application Ser. No. ______ , of Zhuang et al., filed Jul. 26, 2006, for Metal Organic Deposition Precursor Solution Synthesis for Doped SiO₂ Thin Film Deposition, describes fabrication of a precursor solution.

### SUMMARY OF THE INVENTION

A method of fabricating an electroluminescent device includes preparing a wafer; preparing a doped-silicon oxide precursor solution; spin coating the doped-silicon oxide precursor solution onto the wafer to form a doped-silicon oxide thin film on the wafer; baking the wafer and the doped-silicon dioxide thin film at progressively increasing temperatures; rapidly thermally annealing the wafer and the doped-silicon oxide thin film; annealing the wafer and the doped-silicon oxide thin film in a wet oxygen ambient atmosphere; depositing a transparent top electrode on the doped-silicon oxide thin film; patterning and etching the transparent top electrode; and annealing the transparent top electrode, the doped-silicon oxide thin film and the wafer to enhance electroluminescent properties.

It is an object of the invention to provide a method of fabricating an electroluminescent device.

Another object of the invention is to provide a method for fabricating an electroluminescent device having a terbium-doped silicon oxide layer as the photoluminescent layer.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 is a block diagram of the method of the invention.

FIG. 2 depicts the electroluminescent properties of a Tb-doped SiO2 device.

FIG. 3 depicts I-V measurement result of a Tb-doped SiO2 EL device.

FIG. 4 depicts light intensity at 544 nm vs injection current density.

### DETAILED DESCRIPTION OF THE PREFERRED EMBODIMENTS

Precursor solutions for the deposition of Tb-doped SiO₂ thin films are described in the above-identified co-pending Application, which is incorporated herein by reference. Briefly, the precursor is synthesized using SiCl₄ as the silicon source, Tb(NO₃)₃.5H₂O as the rare earth terbium source, and organic solvents. The synthesized precursor solutions are quite stable under typical room temperature storage conditions.

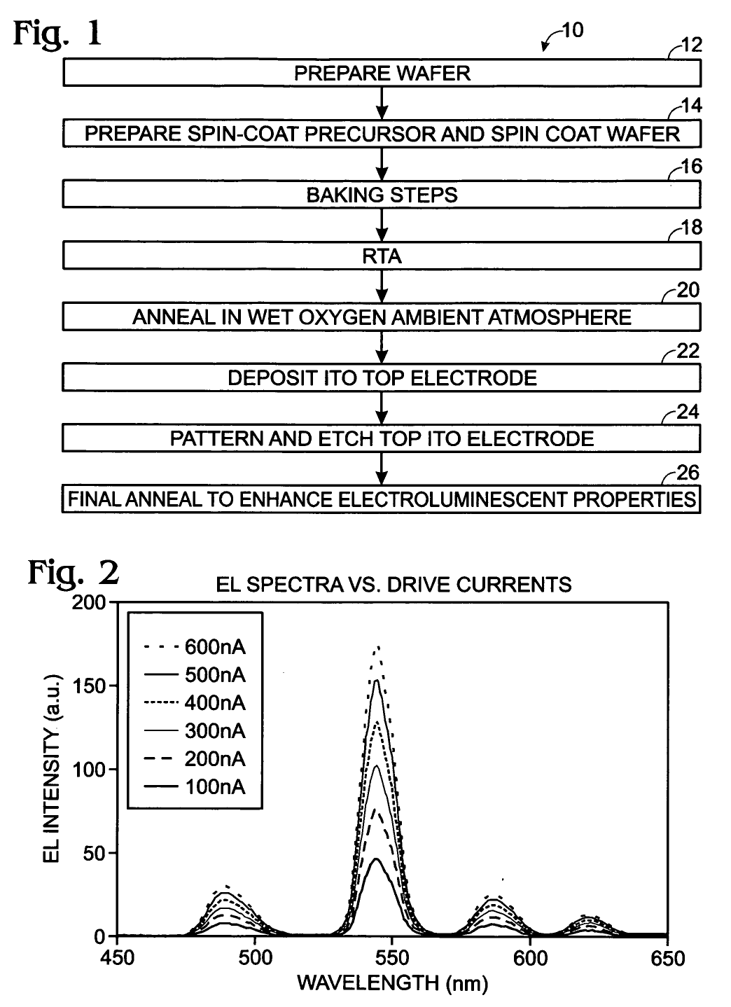

Referring now to FIG. 1, the method of the invention is depicted generally at 10. A wafer is prepared, step 12, usually an n-type silicon wafer. A silicon oxide buffer layer, having a thickness of between about 2 nm to 20 nm may be formed on the wafer as part of the wafer preparation process. A terbium doped silicon oxide (SiO₂) thin film precursor is prepared, as described in the co-pending application, and spin coated onto the wafer, step 14, to form a terbium-doped silicon oxide thin film, which is one form of metal organic deposition. In the preferred embodiment, the precursor solution is spun onto the wafer surface by dispensing approximately 3 ml of the doped silicon oxide precursor onto the spinning wafer, while ramping the spin rate from 800 RPM to 7000 RPM, for a spin time between about 20 seconds to 60 seconds, resulting in a terbium-doped silicon oxide layer having a thickness of between about 50 nm to 200 nm.

The wafer then undergoes a hot plate bake procedure, at successively increasing temperatures of 160°, 220° and 300° C., for one minute each, step 16. This is followed by a RTA bake at temperatures ranging from 500° to 800° C. for 5 to 20 minutes in an oxygen ambient, step 18. To enhance the electroluminescent properties, an oxidation at temperatures ranging from between about 800° to 1050° C. for between about one minute to forty minutes in a wet oxidation ambient is performed, step 20.

A transparent indium-tin oxide (ITO) top electrode layer is sputter deposited, step 22, onto the surface of the Tb-doped SiO₂ thin film, to a thickness of between about 40 nm to 150 nm. After photolithographic patterning and ITO etching, step 24, a final post-anneal at temperatures ranging from between about 800° to 1100° C. for between about one minute to thirty minutes, in a nitrogen ambient is performed, to recover any electroluminescent properties which may have been diminished by etching damage, step 26.

An electroluminescent device fabricated according to the method of the invention includes the following layers, seriatim: transparent top ITO electrode; Tb-doped SiO₂; thermal SiO₂; and an n-type silicon substrate (wafer). The Tb-doped SiO₂ thin film is deposited by spin-coated the specially synthesized precursor onto a n-type silicon wafer, followed by hot plate baking and post-annealing treatments under wet oxidation ambient (H₂ and O₂ in N₂) at temperatures ranging from between about 800° to 1050° C. for between about 1 to 40 minutes. The resultant electroluminescent device exhibited strong electroluminescence, as not previously exhibited by silicon-based electroluminescent layers.

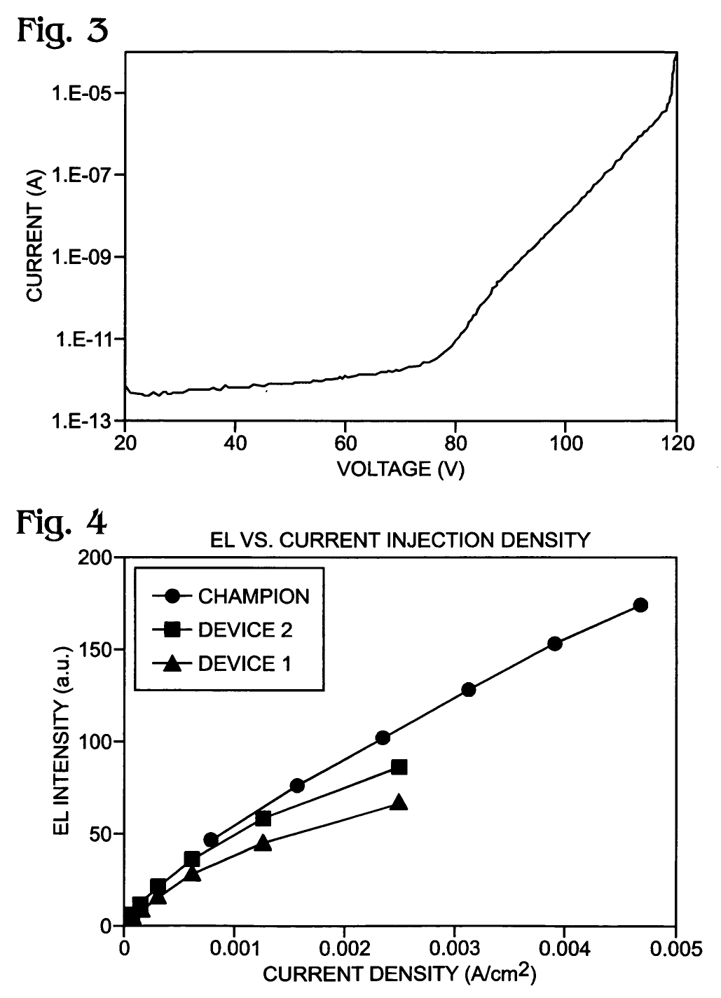

Electroluminescence was observed, as shown in FIG. 2, when a positive voltage was applied to the top electrode. Four discrete emission peaks correspond to the known optical transitions for Tb³⁺. These are assigned as ⁵D₄→⁷Fᵢ, where i=3,4,5, and 6, the brightest being for i=5 at 544 nm. For this particular device, the Tb-doped SiO₂ has a film thickness of 111 nm, formed on a 2.5 nm thick layer of thermal oxide. The ITO thickness was approximately 100 nm. The brightness of the device is dependent upon the applied voltage and the injected current density. The I-V measurements are shown in FIG. 3. The onset of light emission is noticeable when an electric field of approximately 8MV/cm and a current density of 1 E-4 A/cm² is reached. The brightness as a function of current density is depicted in FIG. 4. The relationship is nearly linear, however, at high currents the linearity disappears.

Thus, a method for fabricating an electroluminescent device having a terbium-doped silicon oxide layer as the electroluminescent layer has been disclosed. It will be appreciated that further variations and modifications thereof may be made within the scope of the invention as defined in the appended claims.

We claim:

1. A method of fabricating an electroluminescent device, comprising:
preparing a wafer;
preparing a doped-silicon oxide precursor solution;
spin coating the doped-silicon oxide precursor solution onto the wafer to form a doped-silicon oxide thin film on the wafer;
baking the wafer and the doped-silicon dioxide thin film at progressively increasing temperatures;
rapidly thermally annealing the wafer and the doped-silicon oxide thin film;
annealing the wafer and the doped-silicon oxide thin film in a wet oxygen ambient atmosphere;
depositing a transparent top electrode on the doped-silicon oxide thin film;
patterning and etching the transparent top electrode; and
annealing the transparent top electrode, the doped-silicon oxide thin film and the wafer to enhance electroluminescent properties.

2. The method of claim 1 wherein said preparing a wafer includes preparing an n-type silicon wafer.

3. The method of claim 2 wherein said preparing an n-type silicon wafer include forming a buffer layer of silicon oxide thereon to a thickness of between about 2 nm to 20 nm.

4. The method of claim 1 wherein said preparing a doped-silicon oxide precursor solution includes preparing a terbium-doped silicon oxide precursor solution, wherein the terbium-doped silicon oxide precursor solution is synthesized using SiCl₄ as the silicon source, Tb(NO₃)₃.5H₂O as the rare earth terbium source, and organic solvents.

5. The method of claim 1 wherein said spin coating the doped-silicon oxide precursor solution onto the wafer to form a doped-silicon oxide thin film on the wafer includes spin coating about 3 ml of the doped-silicon oxide precursor solution onto a spinning wafer while the wafer is accelerated from an initial spin rate of about 800 RPM to a spin rate of about 7000 RPM for between about 20 seconds to 60 seconds.

6. The method of claim 1 wherein said spin coating the doped-silicon oxide precursor solution onto the wafer to form a doped-silicon oxide thin film on the wafer includes spin coating a doped-silicon thin film to a thickness of between about 50 nm to 200 nm.

7. The method of claim 1 wherein said baking the wafer and the doped-silicon dioxide thin film at progressively increasing temperatures includes hot plate baking the wafer and the doped-silicon oxide thin film at temperatures of about 160° C., 220° C. and 300° C. for about one minute at each temperature.

8. The method of claim 1 wherein said rapidly thermally annealing the wafer and the doped-silicon oxide thin film includes rapidly thermally annealing the wafer and the doped-silicon oxide thin film at a temperature of between about 500° C. to 800° C. in an oxygen ambient atmosphere for between about five minutes to 20 minutes.

9. The method of claim 1 wherein said annealing the wafer and the doped-silicon oxide thin film in a wet oxygen ambient atmosphere includes annealing at a temperature of between about 800° C. to 1050° C. for between about one minute to forty minutes in a wet atmosphere of hydrogen, oxygen and nitrogen.

10. The method of claim 1 wherein said depositing a transparent top electrode on the doped-silicon oxide thin film includes depositing an electrode of indium-tin oxide to a thickness of between about 40 nm to 150 nm.

11. The method of claim 1 wherein said annealing the transparent top electrode, the doped-silicon oxide thin film and the wafer to enhance electroluminescent properties includes annealing at a temperature of between about 800° C. to 1100° C. for between about one minute to thirty minutes in a nitrogen atmosphere.

12. A method of fabricating an electroluminescent device, comprising:
preparing an n-type silicon wafer;
preparing a terbium doped-silicon oxide precursor solution wherein the terbium-doped silicon oxide precursor solution is synthesized using SiCl₄ as the silicon source, Tb(NO₃)₃.5H₂O as the rare earth terbium source, and organic solvents;
spin coating the terbium doped-silicon oxide precursor solution onto the n-type silicon wafer to form a terbium doped-silicon oxide thin film on the n-type silicon wafer;
baking the n-type silicon wafer and the terbium doped-silicon dioxide thin film at progressively increasing temperatures;
rapidly thermally annealing the n-type silicon wafer and the terbium doped-silicon oxide thin film;
annealing the n-type silicon wafer and the terbium doped-silicon oxide thin film in a wet oxygen ambient atmosphere;
depositing a transparent indium-tin oxide top electrode on the terbium doped-silicon oxide thin film;
patterning and etching the transparent top electrode; and
annealing the transparent top electrode, the terbium doped-silicon oxide thin film and the n-type silicon wafer to enhance electroluminescent properties.

13. The method of claim 12 wherein said preparing an n-type silicon wafer includes forming a buffer layer of silicon oxide thereon to a thickness of between about 2 nm to 20 nm.

14. The method of claim 12 wherein said spin coating the terbium doped-silicon oxide precursor solution onto the n-type silicon wafer to form a terbium doped-silicon oxide thin film on the n-type silicon wafer includes spin coating about 3 ml of the terbium doped-silicon oxide precursor solution onto a spinning n-type silicon wafer while the n-type silicon wafer is accelerated from an initial spin rate of about 800 RPM to a spin rate of about 7000 RPM for between about 20 seconds to 60 seconds.

15. The method of claim 12 wherein said spin coating the terbium doped-silicon oxide precursor solution onto the n-type silicon wafer to form a terbium doped-silicon oxide thin film on the n-type silicon wafer includes spin coating a terbium doped-silicon thin film to a thickness of between about 50 nm to 200 nm.

16. The method of claim 12 wherein said baking the n-type silicon wafer and the terbium doped-silicon dioxide thin film at progressively increasing temperatures includes hot plate baking the n-type silicon wafer and the terbium doped-silicon oxide thin film at temperatures of about 160° C., 220° C. and 300° C. for about one minute at each temperature.

17. The method of claim 12 wherein said rapidly thermally annealing the n-type silicon wafer and the terbium doped-silicon oxide thin film includes rapidly thermally annealing the n-type silicon wafer and the terbium doped-silicon oxide thin film at a temperature of between about 500° C. to 800° C. in an oxygen ambient atmosphere for between about five minutes to 20 minutes.

18. The method of claim 12 wherein said annealing the n-type silicon wafer and the terbium doped-silicon oxide thin film in a wet oxygen ambient atmosphere includes annealing at a temperature of between about 800° C. to 1050° C. for between about one minute to forty minutes in a wet atmosphere of hydrogen, oxygen and nitrogen.

19. The method of claim 12 wherein said depositing an electrode of indium-tin oxide includes depositing an electrode to a thickness of between about 40 nm to 150 nm.

20. The method of claim 12 wherein said annealing the transparent top electrode, the terbium doped-silicon oxide thin film and the n-type silicon wafer to enhance electroluminescent properties includes annealing at a temperature of between about 800° C. to 1100° C. for between about one minute to thirty minutes in a nitrogen atmosphere.
